(19) United States
(12) Patent Application Publication
(10) Pub. No.: US 2006/0201546 A1
(43) Pub. Date: Sep. 14, 2006

(54) Stack type photoelectric conversion device

(75) Inventor: Daisuke Yokoyama, Minami-Ashigara-Shi (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/362,777

(22) Filed: Feb. 28, 2006

(30) Foreign Application Priority Data
Feb. 28, 2005 (JP) P. 2005-054503
Jun. 27, 2005 (JP) P. 2005-186935

(51) Int. Cl. H01L 31/00

(52) U.S. Cl. 136/263

(57) ABSTRACT

A photoelectric conversion device comprising: a substrate including a photoelectric conversion part; at least one photoelectric conversion layer provided above the substrate; and an optical film for increasing a reflectivity of light within a wavelength range capable of being absorbed by the photoelectric conversion layer, wherein the optical film is provided between the photoelectric conversion part and the photoelectric conversion layer.

### FIELD OF THE INVENTION

This invention relates to a photoelectric conversion device of the photoelectric conversion layer-stacked type.

### BACKGROUND OF THE INVENTION

A conventional solid-state image pickup device having a photoelectric conversion layer formed almost on the same plane as a charge transfer pathway suffers from problems that an increase in the pixel integration degree results in wasting the incident light in a color filter and that the thus enlarged pixels (being almost in the same size as the light wavelength) prevent the light from transmitting into the photoelectric conversion layer. In such a device, moreover, the three colors RGB are detected at different positions, which sometimes brings about color separation and, in its turn, the occurrence of false color. To avoid these problems, an optical low pass filter should be employed, which causes an additional problem of light loss due to this filter.

There has been proposed a color sensor wherein a stacked light-receiving part is constructed by using the wavelength-dependency of the absorption coefficient of Si and thus color separation is carried out in the depth direction thereof (U.S. Pat. No. 5,965,875, U.S. Pat. No. 6,632,701 and JP-A-7-38136). However, this device suffers from a problem that the stacked light-receiving part shows a broad wavelength-dependency of the spectral sensitivity and thus only insufficient color separation can be made. In particular, blue and green color separation is insufficient.

To solve this problem, there has been proposed a system comprising forming a green sensor above Si and receiving blue and red lights by Si (JP-A-2003-332551). As an appropriate means of absorbing green light and transmitting blue and red lights in this case, an organic film serving as a photoelectric conversion layer is proposed.

On the other hand, there has been also proposed a system which comprises stacked multiple photoelectric conversion layers made of amorphous silicone on a substrate and sandwiching a semitransmissive reflection layer between photoelectric conversion layers of individual colors (JP-A-2004-335626)

### SUMMARY OF THE INVENTION

However, the system comprising forming a green sensor above Si and receiving blue and red lights by Si (JPA-2003-332551) has the following problems. (1) Although a thin organic film is needed to achieve a high photoelectric conversion efficiency at a low bias voltage, such a film cannot sufficiently absorb green light. As a result, the sensitivity of the green photoelectric conversion layer is lowered. (2) In the case of using a pigment dye or the like having a high photoelectric conversion efficiency, it shows a broad spectral sensitivity and, therefore, absorbs not only green light but also blue and red lights. As a result, the spectral sensitivity of the green light-absorbing layer becomes broad and Si located below cannot sufficiently receive blue and red lights.

Further, the system comprising stacked multiple photoelectric conversion layers made of amorphous silicone on a substrate and sandwiching a semitransmissive reflection layer between photoelectric conversion layers of individual colors (JP-A-2004-335626) suffers from the following problems. (1) Amorphous silicone can hardly achieve a sharp color separability and a single layer thickness should be 1 μm or more for sufficiently absorbing light in the visible wavelength region. (2) In the case of stacked multiple photoelectric conversion layers on a substrate, electrodes located above and below each photoelectric conversion layer should be connected to the transfer pathway on the Si substrate, which makes the fabrication process highly complicated. The process becomes more troublesome with an increase in the photoelectric conversion layer thickness.

Under these circumstances, an object of the invention is to provide a photoelectric conversion device which has a high sensitivity, enables sharp color separation without causing a false color and can provide a realistic color. In particular, an object of the invention is to provide a photoelectric conversion device wherein the sensitivity of a green photoelectric conversion layer is increased and color separation is improved to give an improved spectral sensitivity of the photoelectric conversion layer.

As the results of intensive studies, the inventor has found out that by forming an optical interference film comprising multiple layers capable of increasing the reflectivity of green light between, for example, an Si substrate having an internally located blue and red photoelectric conversion part and an organic green photoelectric conversion layer located above it, the sensitivity of the green photoelectric conversion layer is improved due to the reflected green light absorption while the transmission of green light into the lower part of the internally located photoelectric conversion part in the Si substrate is reduced, thereby improving color separation, and that the spectral sensitivity of the green light-absorbing organic photoelectric conversion layer can be sharpened due to the interference effect of the green light reflected from the optical interference film in the organic photoelectric conversion layer. By further generalizing these findings, the invention has been accomplished.

Accordingly, the constitutions specifying the present invention are as following items.

(1) A photoelectric conversion device wherein one or more photoelectric conversion layers are provided above a substrate having an internally-located photoelectric conversion part, and an optical film for increasing the reflectivity of light within the wavelength range capable of being absorbed by the photoelectric conversion layer is provided between the photoelectric conversion part located in the substrate and the photoelectric conversion layer located above the substrate.

(2) The photoelectric conversion device as described in the item (1), wherein the photoelectric conversion layer located above the substrate has such a thickness that the spectral sensitivity thereof is sharpened by the interference effect due to the light reflected from the optical film.

(3) The photoelectric conversion device as described in the item (1) or (2), wherein the photoelectric conversion part located in the substrate has multiple first electrically conductive areas and multiple second electrically conductive areas of the opposite conductive type to the first electrically conductive areas, and the photoelectric conversion part is formed so that the first conductive type/second conductive type junction face has appropriate depths mainly for the photoelectric conversion of lights in any two of blue, green and red wavelength ranges respectively, while the photoelectric conversion layer located above the substrate is a photoelectric conversion layer responding mainly to the remainder wavelength range differing from these two wavelength ranges.

(4) The photoelectric conversion device as described in the item (3), wherein the photoelectric conversion part located in the substrate is a photoelectric conversion part that is formed so as to give appropriate depths mainly for the photoelectric conversion of lights in the blue and red wavelength ranges respectively, while the photoelectric conversion layer located above the substrate is an organic photoelectric conversion layer responding mainly to the intermediate wavelength range between these two wavelength ranges.

(5) The photoelectric conversion device as described in any one of the items (1) to (4), wherein the photoelectric conversion part located in the substrate is made of Si.

(6) The photoelectric conversion device as described in the item (5), wherein a p substrate or an n substrate having p-well is employed as the Si substrate and the photoelectric conversion part has an npn structure or a pnpn structure from the surface.

(7) The photoelectric conversion device as described in the item (1) or (2), wherein the photoelectric conversion part located in the substrate is a photoelectric conversion part that is formed so as to photoelectrically convert mainly lights in any two of blue, green and red wavelength ranges at different positions concerning the face direction perpendicular to the light-incident direction within the substrate, while the photoelectric conversion layer located above the substrate is a photoelectric conversion layer responding mainly to the remainder wavelength range differing from these two wavelength ranges.

(8) The photoelectric conversion device as described in the item (7), wherein the photoelectric conversion part located in the substrate is a photoelectric conversion part that is formed so as to photoelectrically convert mainly lights in the blue and red wavelength ranges respectively, while the photoelectric conversion layer located above the substrate is an organic photoelectric conversion layer responding mainly to the intermediate wavelength range between these two wavelength ranges.

(9) The photoelectric conversion device as described in the item (7) or (8), wherein the photoelectric conversion part located in the substrate is made of Si.

(10) The photoelectric conversion device as described in the item (9), wherein a p substrate or an n substrate having p-well is employed as the Si substrate and the photoelectric conversion part has an n structure or a pn structure from the surface.

(11) A photoelectric conversion device wherein between multiple organic photoelectric conversion layers responding to lights in different wavelength ranges, an optical film being capable of increasing the reflectivity of light within the wavelength range absorbed by the organic photoelectric conversion layer located in the light-incident side is formed.

(12) The photoelectric conversion device as described in the item (11), wherein the organic photoelectric conversion layer located in the light-incident side has such a thickness that the spectral sensitivity thereof is sharpened by the interference effect due to the light reflected from the optical film.

(13) The photoelectric conversion device as described in the item (11) or (12), wherein the multiple organic photoelectric conversion layers respond mainly to any of lights in the blue, green and red wavelength ranges respectively.

(14) The photoelectric conversion device as described in any one of the items (11) to (13), wherein an organic photoelectric conversion layer responding mainly to light in the green wavelength range is formed at the closest position to the light-incident side and an optical film being capable of increasing the reflectivity of green light is formed between this green light-responsive organic photoelectric conversion layer and the organic photoelectric conversion layer located at the second closest position to the light-incident side.

(15) A photoelectric conversion device having multiple organic photoelectric conversion layers responding to lights in different wavelength ranges and an optical film which is located in the opposite side to the light-incident side concerning all of the organic photoelectric conversion layers and capable of increasing the reflectivity of light in the wavelength range absorbed by at least one of the organic photoelectric conversion layers.

(16) The photoelectric conversion device as described in the item (15), wherein at least one organic photoelectric conversion layer has such a thickness that the spectral sensitivity thereof is sharpened by the interference effect due to the light reflected from the optical film.

(17) The photoelectric conversion device as described in the item (15) or (16), wherein the multiple organic photoelectric conversion layers respond mainly to any of lights in the blue, green and red wavelength ranges respectively.

(18) The photoelectric conversion device as described in any one of the items (15) to (17), wherein an organic photoelectric conversion layer responding mainly to light in the green wavelength range is formed at the closest position to the light-incident side and an optical film being capable of increasing the reflectivities of all of lights in the blue, green and red wavelength ranges is formed.

(19) The photoelectric conversion device as described in any one of the items (1) to (3), (5) to (7), (9) to (13) and (15) to (17), wherein the optical film is an optical film that reflects light having any one of wavelengths 460 nm, 540 nm and 620 nm at a ratio of 50% or more and transmits lights of the remainder two wavelengths at a ratio of 70% or more.

(20) The photoelectric conversion device as described in any one of the items (1) to (17), wherein the optical film is an optical film that reflects light having a wavelength of 540 nm at a ratio of 50% or more and transmits lights of 460 nm and 620 nm at a ratio of 70% or more.

(21) The photoelectric conversion device as described in any one of the items (1) to (20), wherein the optical film contains multiple insulator layers.

(22) The photoelectric conversion device as described in the item (21), wherein the optical film has a structure comprising multiple layers made of two materials, the refraction index ratio (i.e., the value determined by dividing the higher refraction index by the lower refraction index) of which is from 1.1 to 1.3, alternately stacked and at least one of these two materials is an insulator.

(23) The photoelectric conversion device as described in the item (21) or (22), wherein the optical film contains a layer made of a material selected from among silicon oxide, silicon nitride, silicon oxynitride, titanium oxide, alumina, zirconium oxide, hafnium oxide, magnesium fluoride and calcium fluoride.

(24) The photoelectric conversion device as described in any one of the items (1) to (23), wherein the optical film is formed by a method selected from among the vacuum vapor deposition method, the sputtering method, the plasma CVD method, the Cat-CVD method and the laser ablation method.

According to the invention, it is possible to provide a photoelectric conversion device which has a high sensitivity, enables sharp color separation without causing a false color and can provide a realistic color. In particular, the invention makes it possible to provide a photoelectric conversion device wherein the sensitivity of a green photoelectric conversion layer is increased and color separation is improved to give an improved spectral sensitivity of the photoelectric conversion layer.

### BRIEF DESCRIPTION OF THE DRAWINGS

FIG. 1 is a drawing which schematically shows the photoelectric conversion device of the invention according to Example 1.

FIG. 2 is a drawing which schematically shows the photoelectric conversion device of the invention according to Example 2.

FIG. 3 is a drawing which schematically shows the photoelectric conversion device of the invention according to Example 3.

FIG. 4 is a drawing showing increase and sharpening in absorbance by the optical film of the invention (calculated data).

FIG. 5 is a drawing showing absorption spectra (measured data).

FIG. 6 is a drawing showing reflectivity of optical film cited in Example.

FIG. 7 is a drawing showing increase in the absorption factor of organic film due to the formation of interference reflection layer.

Description of the Reference Numericals and Signs:

### DETAILED DESCRIPTION OF THE INVENTION

(Photoelectric Conversion Device)

Next, the stack type photoelectric conversion device of the invention will be illustrated.

The photoelectric conversion device comprises an electromagnetic wave absorption/photoelectric conversion part and a charge storage/transfer/reading part for the charge generated by the photoelectric conversion.

The electromagnetic wave absorption/photoelectric conversion part has a stacked structure composed of at least two layers whereby at least blue light, green light and red light can be absorbed and photoelectrically converted. The blue light absorption layer (B) can absorb light having wavelength of from 400 nm to 500 nm and the absorption factor of the peak wavelength in this region is preferably 50% or more. The green light absorption layer (G) can absorb light having wavelength of from 500 nm to 600 nm and the absorption factor of the peak wavelength in this region is preferably 50% or more. The red light absorption layer (R) can absorb light having wavelength of from 600 nm to 700 nm and the absorption factor of the peak wavelength in this region is preferably 50% or more. These layers may be formed in any order. In a stacked structure composed of three layers, use may be made of the orders of, from the upper side, BGR, BRG, GBR, GRB, RBG and RGB. It is preferable that C is provided as the uppermost layer. In a stacked structure composed of two layers wherein an R layer is provided as the upper layer, BG layers are provided on a single plane to form the lower layer. In the case where a B layer is provided as the upper layer, GR layers are provided on a single plane to form the lower layer. In the case where a G layer is provided as the upper layer, BR layers are provided on a single plane to form the lower layer. It is preferable that the G layer is provided as the upper layer while the BR layers are provided on a single plane as the lower layer. In such a case where two light absorption layers are provided on a single plane as the lower layer, it is preferable to form a filter layer (for example, in a mosaic structure) for color separation on the upper layer or between the upper and lower layers. It is also possible in some cases to form additional layer(s) as the fourth layer or higher or On the same plane.

The charge storage/transfer/reading part is provided under the electromagnetic wave absorption/photoelectric conversion part. It is preferred that the electromagnetic wave absorption/photoelectric conversion part in the lower layer also serves as the charge storage/transfer/reading part.

The electromagnetic wave absorption/photoelectric conversion part comprises an organic layer, an inorganic layer or a combination of an organic layer with an inorganic layer. Organic layers may be B/G/R layers. Alternatively, inorganic layers may be B/G/R layers. A combination of an organic layer with an inorganic layer is preferred. Fundamentally, one or two inorganic layers are formed in the case of forming one organic layer, and one inorganic layer is formed in the case of forming two organic layers. In the case of forming one organic layer and one inorganic layer, the inorganic layer forms electromagnetic wave absorption/photoelectric conversion parts in two or more colors on a single plane. It is preferable that the upper layer is an organic layer serving as the G layer while the lower layers are inorganic layers comprising the B layer and the R layer in this order from the upper side. It is also possible in some cases to form additional layer(s) as the fourth layer or higher or on the same plane. In the case where organic layers are B/G/R layers, the charge storage/transfer/reading part is formed under these layers. In the case of using an inorganic layer as the electromagnetic wave absorption/photoelectric conversion part, the inorganic layer also serves as the charge storage/transfer/reading part.

(Illustration of Organic Layer)

Now, the organic layer in the invention will be illustrated. In the invention, an electromagnetic wave absorption/photoelectric conversion part made of an organic layer comprises an organic film located between a pair of electrodes. The organic layer is made up of an electromagnetic wave absorption part, an electron transportation part, a photoelectric conversion part, a hole transportation part, an electron blocking part, a hole blocking part, a crystallization prevention part, electrodes, an interlayer contact improvement part and so on which are piled up or mixed together. It is preferable that the organic layer contains an organic p-type compound or an organic n-type compound.

The organic p-type semiconductor (compound), which is a donor type organic semiconductor (compound), is typified mainly by a hole-transporting organic compound, i.e., an organic compound being liable to donate electron. To speak in greater detail, it means an organic compound having a lower ionization potential in the case of using two organic materials in contact with each other. That is to say, any compound capable of donating electron can be used as the donor type organic compound. For example, use can be made of triarylamine compounds, benzidine compounds, pyrazoline compounds, styrylamine compounds, hydrazone compounds, triphenylmethane compounds, carbazole compounds, polysilane compounds, thiophene compounds, phthalocyanine compounds, cyanine compounds, merocyanine compounds, oxonole compounds, polyamine compounds, indole compounds, pyrrole compounds, pyrazole compounds, polyarylene compounds, condensed ring aromatic carbon ring compounds (naphthalene derivatives, anthracene derivatives, phenanthrene derivatives, tetracene derivatives, pyrene derivatives, perylene derivatives and fluoranthene derivatives), metal complexes having nitrogen-containing heterocyclic compounds as a ligand and so on. However, the invention is not restricted to these compounds and use may be made, as the donor type organic semiconductor, of any organic compound which has a lower ionization potential than the organic compound employed as the n-type (acceptor type) compound as discussed above.

The organic n-type semiconductor (compound), which is an acceptor type organic semiconductor (compound), is typified mainly by an electron-transporting compound, i.e., an organic compound being liable to accept electron. To speak in greater detail, it means an organic compound having a higher electron affinity in the case of using two organic materials in contact with each other. That is to say, any compound capable of accepting electron can be used as the acceptor type organic compound. For example, use can be made of condensed ring aromatic carbon ring compounds (naphthalene derivatives, anthracene derivatives, phenanthrene derivatives, tetracene derivatives, pyrene derivatives, perylene derivatives and fluoranthene derivatives), 5- to 7-membered heterocyclic compounds having a nitrogen atom, an oxygen atom or a sulfur atom (for example, pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrralizine, pyrrolopyridine, thiadiazolopyridine, dibenzazepine and tribenzazepine), polyarylene compounds, fluorene compounds, cyclopentadiene compounds, silyl compounds, metal complexes having nitrogen-containing heterocyclic compounds as a ligand and so on. However, the invention is not restricted to these compounds and use may be made, as the acceptor type organic semiconductor, of any organic compound which has a higher electron affinity than the organic compound employed as the donor type organic compound as discussed above.

Although any compounds are usable as the p-type organic dye or the n-type organic dye, preferable examples thereof include cyanine dyes, styryl dyes, hemicyanine dyes, merocyanine dyes (including zeromethine merocyanine (simple merocyanine)), three-nuclear merocyanine dyes, four-nuclear merocyanine dyes, rhodacyanine dyes, complex cyanine dyes, complex merocyanine dyes, aro polar dyes, oxonole dyes, hemioxonole dyes, squarium dyes, croconium dyes, azamethine dyes, coumarine dyes, arylidene dyes, anthraquinone dyes, triphenylmethane dyes, azo dyes, azomethine dyes, spiro compounds, metallocene dyes, fluorenone dyes, flugide dyes, perylene dyes, phenazine dyes, phenothiazine dyes, quinone dyes, indigo dyes, diphenylmethane dyes, polyene dyes, acridine dyes, acridinone dyes, diphenylamine dyes, quinacridone dyes, quinophthalone dyes, phenoxazine dyes, phthaloperylene dyes, porphyrin dyes, chlorophyll dyes, phthalocyanine dyes, metal complex dyes, condensed ring aromatic carbon ring compounds (naphthalene derivatives, anthracene derivatives, phenanthrene derivatives, tetracene derivatives, pyrene derivatives, perylene derivatives and fluoranthene derivatives) and so on.

Next, a metal complex compound will be illustrated. A metal complex compound is a metal complex which carries a ligand having at least one nitrogen atom, oxygen atom or sulfur atom and coordinating with a metal. Although the metal ion in such a metal complex is not particularly restricted, preferable examples thereof include beryllium ion, magnesium ion, aluminum ion, gallium ion, zinc ion, indium ion and tin ion, still preferably beryllium ion, aluminum ion, gallium ion or zinc ion, and still preferably aluminum ion or zinc ion. As the ligand contained in the above metal complex, various publicly known ligands may be cited. For example, use can be made of ligands reported in Photochemistry and Photophysics of Coordination Compounds, published by Springer-Verlag, H. Yersin (1987) and Yuki Kinzoku Kagaku-Kiso to Oyo, published by Shokabo, Akio Yamamoto (1982) and so on.

Preferable examples of the above ligand include nitrogen-containing heterocyclic ligands (preferably having from 1 to 30 carbon atoms, still preferably from 2 to 20 carbon atoms, and particularly preferably form 3 to 15 carbon atoms; including both of monodentate ligands and higher, bidentate ligands being preferred, e.g., pyridine ligands, bipyridyl ligands, quinolynol ligands, hydroxyphenylazole ligands such as hydroxyphenylbenzimidazole ligand, hydroxyphenylbenzoxazole ligand and hydroxyphenylimidazole ligand), alkoxy ligands (preferably having from 1 to 30 carbon atoms, still preferably from 1 to 20 carbon atoms and particularly preferably from 1 to 10 carbon atoms, such as methoxy, ethoxy, butoxy and 2-ethylhyxyloxy), aryloxy ligands (preferably having from 6 to 30 carbon atoms, still preferably from 6 to 20 carbon atoms and particularly preferably from 6 to 12 carbon atoms, such as phenyloxy, 1-naphthyloxy, 2-naphthyloxy, 2,4,6-trimethylphenyloxy and 4-biphenyloxy), heteroaryloxy ligands (preferably having from 1 to 30 carbon atoms, still preferably form 1 to 20 carbon atoms and particularly preferably from 1 to 12 carbon atoms, such as pyridyloxy, pyrazyloxy, pyrimidyloxy and quinolyloxy), alkylthio ligands (preferably having from 1 to 30 carbon atoms, still preferably from 1 to 20 carbon atoms and particularly preferably from 1 to 12 carbon atoms, such as methylthio and ethylthio), arylthio ligands (preferably having from 6 to 30 carbon atoms, still preferably from 6 to 20 carbon atoms and particularly preferably from 6 to 12 carbon atoms, such as phenylthio), heterocycle-substituted thio ligands (preferably having from 1 to 30 carbon atoms, still preferably from 1 to 20 carbon atoms and particularly preferably from 1 to 12 carbon atoms, such as pyridylthio, 2-benzimidazolylthio, 2-benzoxazolylthio and 2-benzthiazolylthio) and siloxy ligands (preferably having from 1 to 30 carbon atoms, still preferably from 3 to 25 carbon atoms and particularly preferably from 6 to 20 carbon atoms, such as triphenylsiloxy group, triethoxysiloxy group and triisopropylsiloxy group). Still preferable examples thereof include nitrogen-containing heterocyclic ligands, aryloxy ligands, heteroaryloxy groups and siloxy ligands, and nitrogen-containing heterocyclic ligands, aryloxy ligands and siloxy ligands are still preferable.

In the invention, it is preferable to contain a photoelectric conversion layer (a photosensitive layer) which has a p-type semiconductor layer and an n-type semiconductor layer between a pair of electrodes and also has a bulk heterojunction layer containing the p-type semiconductor and the n-type semiconductor as an intermediate layer between these semiconductor layers. In this case, the shortage of the organic layer of having a short carrier diffusion length can be overcome owing to the bulk heterojunction structure in the organic layer and thus the photoelectric conversion efficiency can be increased. The bulk heterojunction structure is described in detail in Japanese Patent Application No. 2004-080639.

It is preferable in the invention to contain a photoelectric conversion layer (a photosensitive layer which has two or more repeating structure units of a pn junction layer comprising a p-type semiconductor layer and an n-type semiconductor layer between a pair of electrodes (a tandem structure). It is still preferable to insert a thin layer made of an electrically conductive material between these repeating structure units. Although the number of the repeating structure units of the pn junction layers (the tandem structure) is not restricted, it preferably ranges from 2 to 50, still preferably from 2 to 30 and particularly preferably 2 or 10, from the viewpoint of achieving a high photoelectric conversion efficiency. As the electrically conductive material, silver or gold is preferable and silver is most desirable. The tandem structure is described in detail in Japanese Patent Application No. 2004-079930.

In a photoelectric conversion layer having a p-type semiconductor layer and an n-type semiconductor layer between a pair of electrodes (preferably a mixture/dispersion (bulk heterojunction) layer), a photoelectric conversion layer containing an organic compound having controlled orientation at least in one of the p-type semiconductor and the n-type semiconductor is preferable and a photoelectric conversion layer containing organic compounds having (possibly) controlled orientation in both of the p-type semiconductor and the n-type semiconductor is still preferred. As the organic compound to be used in the organic layer of the photoelectric conversion layer, it is preferable to employ one having a π-conjugated electron. It is favorable to use a compound having been oriented to give an angle of this π electron plane which is not perpendicular but as close to parallel as possible to the substrate (the electrode substrate). The angle to the substrate is preferably 0° or larger but not larger than 80°, still preferably 0° or larger but not larger than 60°, still preferably 0° or larger but not larger than 40°, still preferably 0° or larger but not larger than 20°, particularly preferably 0° or larger but not larger than 10° and most desirably 0° (i.e., being parallel to the substrate). The organic layer comprising the organic compound with controlled orientation as described above may be at least a part of the whole organic layer. It is preferable that the part with controlled orientation amounts to 10% or more based on the whole organic layer, still preferably 30% or more, still preferably 50% or more, still preferably 70% or more, particularly preferably 90% or more and most desirably 100%. In this construction, the shortage of the organic layer of having a short carrier diffusion length can be overcome by controlling the orientation of the organic compound in the organic layer and thus the photoelectric conversion efficiency can be increased.

In the where the organic compound has controlled orientation, it is still preferable that the heterojunction plane (for example, a pn junction plane) is not parallel to the substrate. It is favorable that the organic compound is oriented so that the heterojunction plane is not parallel to the substrate (the electrode substrate) but as close to perpendicular as possible thereto, The angle to the substrate is preferably 10° or larger but not larger than 90°, still preferably 30° or larger but not larger than 90°, still preferably 50° or larger but not larger than 90°, still preferably 70° or larger but not larger than 90°, particularly preferably 80° or larger but not larger than 90° and most desirably 90° (i.e., being perpendicular to the substrate). The layer of the compound with controlled heterojunction plane as described above may be a part of the whole organic layer. The part with controlled orientation preferably amounts to 10% or more based on the whole organic layer, still preferably 30% or more, still preferably 50% or more, still preferably 70% or more, particularly preferably 90% or more and most desirably 100%. In such a case, the area of the heterojunction plane in the organic layer is enlarged and, in its turn, electrons, holes, electron-hole pairs, etc. formed in the interface can be carried in an increased amount, which makes it possible to improve the photoelectric conversion efficiency. The photoelectric conversion layer (a photosensitive layer) in which the orientation is controlled in both of the heterojunction plane and the π-electron plane as described above, the photoelectric conversion efficiency can be particularly improved. These states are described in detail in Japanese Patent Application No. 2004-079931.

From the viewpoint of light absorption, a larger thickness of an organic dye layer is preferred. By taking the percentage not contributing to charge separation into consideration, however, the thickness of the organic dye layer according to the invention is preferably 30 nm or more but not more than 300 nm, still preferably 50 nm or more but not more than 250 nm, and particularly preferably 80 nm or more but not more than 200 nm.

[Method of Forming Organic Layer]

The layers containing these organic compounds can be formed by a dry layer-forming method or a wet layer-forming method. Specific examples of the dry layer-forming method include physical vapor phase epitaxy methods such as the vacuum vapor deposition method, the sputtering method, the ion plating method and the MBE method, and CVD methods such as the plasma polymerization method. Examples of the wet layer-forming method include the casting method, the spin coating method, the dipping method and the LB method.

In the case of using a polymer compound as at least one of the p-type semiconductor (compound) and the n-type semiconductor (compound), it is favorable to form the layer by a wet layer-forming method which can be easily carried out, When a dry layer-forming method such as the vapor deposition method is employed, it is highly difficult to employ a polymer compound because of a fear of decomposition. In such a case, use may be preferably made of a corresponding oligomer as a substitute for the polymer. In the case of using a low-molecular weight compound in the invention, use is preferably made of a dry layer-forming method and the vacuum vapor deposition method is particularly preferred. Fundamental parameters in the vacuum vapor deposition method include a method of heating a compound (e.g., the resistance heating method, the electron beam heating/deposition method or the like), the shape of the deposition source such as a crucible or a boat, the degree of vacuum, the deposition temperature, the substrate temperature, the deposition rate and so on, To achieve uniform deposition, it is favorable to carry out the deposition while rotating the substrate. A higher degree of vacuum is preferred. The vacuum vapor deposition is performed preferably at a degree of vacuum of 10⁻² Pa or lower, more preferably 10⁻⁴ Pa or lower and particularly preferably 10⁻⁶ Pa or lower. It is preferable to carry out all of the vapor deposition steps in vacuo. Fundamentally, the subject compound should be prevented from direct contact with the external oxygen or moisture. The vacuum vapor deposition conditions as described above should be strictly controlled, since the crystalinity, amorphous properties, density and denseness of the organic film are affected thereby, It is preferable to PI or PID control the deposition rate with the use of a film thickness monitor such as a crystal oscillator or an interferometer. In the case of depositing two or more compounds at the same time, use may be preferably made of the co-deposition method, the flash deposition method or the like.

(Electrode)

The electromagnetic wave absorption/photoelectric conversion part comprising organic layers according to the invention is located between a pair of electrodes respectively serving as a pixel electrode and a counter electrode, It is preferable that the lower layer serves as the pixel electrode.

It is preferable that the counter electrode takes out positive holes from a hole-transporting photoelectric conversion layer or a hole-transporting layer. As a material of the counter electrode, use may be made of a metal, an alloy, a metal oxide, an electrically conductive compound or a mixture thereof. It is preferable that the pixel electrode can take out electrons from an electron-transporting photoelectric conversion layer or an electron-transporting layer. It is selected by considering the adhesiveness to the adjacent layers such as the electron-transporting photoelectric conversion layer and the electron-transporting layer, electron affinity, ionization potential, stability and so on. Specific examples thereof include electrically conductive metal oxides such as tin oxide, zinc oxide, indium oxide and indium tin oxide (ITO), metals such as gold, silver, chromium and nickel, mixtures or stacks of these metals with electrically conductive metal oxides, inorganic conductive materials such as copper iodide and copper sulfide, organic conductive materials such as polyaniline, polythiophene and polypyrrole, silicone compounds and stacks thereof with ITO. Electrically conductive metal oxides are preferable and ITO and IZO are still preferable from the viewpoints of productivity, high conductivity, transparency and so on. The layer thickness may be appropriately selected depending on material, In usual, it is 10 nm or more but not more than 1 μm, still preferably 30 nm or more but not more than 500 nm and still preferably 50 nm or more but not more than 300 nm.

The pixel electrode and the counter electrode may be constructed by various methods depending on materials. In the case of using ITO, for example, a layer may be formed by the electron beam heat deposition method, the sputtering method, the resistance heat deposition method, the chemical reaction method (sol-gel method, etc.) or the method of coating with an indium tin oxide dispersion. In the case of using ITO, it is also possible to perform the UV-ozone treatment, the plasma treatment or the like.

It is preferable to construct a transparent electrode film under plasma-free conditions. By constructing the transparent electrode film under plasma-free conditions, effects of plasma on the substrate can be minimized and thus favorable photoelectric conversion characteristics can be established. The term “plasma-free” as used herein means a state wherein no plasma generates in the course of forming a transparent electrode film or the distance between a plasma source and a substrate is 2 cm or longer, preferably 10 cm or longer and still preferably 20 cm or longer and, therefore, plasma is lessened until it reaches the substrate.

As a device wherein no plasma generates during the film-formation of a transparent electrode film, use can be made of, for example, an electron beam heat deposition device (an ES deposition device)and a pulse laser deposition device. Namely, use can be made of an EB deposition device or a pulse laser deposition device reported in Tomei Dodenmaku no Shintenkai, supervised by Yutaka Sawada (CMC, 1999); Tomei Dodenmaku no Shintenkai II, supervised by Yutaka Sawada (CMC, 2002); Tomei Dodenmaku no Gijutsu, Japan Society for the Promotion of Science (Ohm, 1999) and reference documents attached thereto. A method of forming a transparent electrode film by using an EB deposition device will be called the EB deposition method while a method of forming a transparent electrode film with the use of a pulse laser deposition device will be called the pulse laser deposition method hereinafter.

As examples of a device having a distance between a plasma source and a substrate of 2 cm or longer and, therefore, plasma is lessened until it reaches the substrate (hereinafter referred to as a plasma-free film forming device), a counter target sputtering device and an arc plasma deposition device may be cited. Namely, use can be made of devices reported in Tomei Dodenmaku no Shintenkai, supervised by Yutaka Sawada (CMC, 1999); Tomei Dodenmaku no Shintenkai II, supervised by Yutaka Sawada (CMC, 2002); Tomei Dodenmaku no Gijutsu, Japan Society for the Promotion of Science (Ohm, 1999) and reference documents attached thereto.

Now, the electrodes in the electromagnetic wave absorption/photoelectric conversion part of the invention will be illustrated in greater detail. The photoelectric conversion layer in the organic layer, which is located between a pixel electrode film and a counter electrode film, may comprise an interelectrode material or the like. The term “pixel electrode film” means an electrode film constructed in the upper part of the substrate on which a charge storage/transfer/reading part is formed. It is usually divided for individual pixels so that a signal charge converted by the photoelectric conversion layer can be read for each pixel on the charge storage/transfer/signal reading circuit substrate to give an image.

The term “counter electrode film” means an electrode film having a function of sandwiching the photoelectric conversion film together with the pixel electrode film to thereby emit a signal charge having a polarity opposite to the signal charge. Since it is unnecessary to divide the emission of the signal charge for individual pixels, pixels usually have a counter electrode film in common. Thus, it is sometimes called a common electrode film.

The photoelectric conversion film is located between the pixel electrode film and the counter electrode film. The photoelectric conversion function is established by the photoelectric conversion film, the pixel electrode film and the counter electrode film.

In the case where a single organic layer is stacked on a substrate, the photoelectric conversion layer stack is composed of, for example, a substrate and a pixel electrode film (fundamentally being a transparent electrode film), a photoelectric conversion film and a counter electrode film (a transparent electrode film) which are stacked on the substrate in this order, though the invention is not restricted thereto.

In the case where two organic layers are stacked on a substrate, the photoelectric conversion layer stack is composed of, for example, a substrate and a pixel electrode film (fundamentally being a transparent electrode film), a photoelectric conversion film, a counter electrode film (a transparent electrode film), an interlayer insulating film, a pixel electrode film (fundamentally being a transparent electrode film), a photoelectric conversion film and a counter electrode film (a transparent electrode film) which are stacked on the substrate in this order.

The material for making the transparent electrode film constituting the photoelectric conversion part in the invention is preferably a material which is usable in film-formation by using a plasma-free film forming device, an EB deposition device or a pulse laser deposition device. Preferable examples thereof include metals, alloys, metal oxides, metal nitrides, metal borides, organic conductive compounds and mixtures thereof. Specific examples thereof include conductive metal oxides such as tin oxide, zinc oxide, indium oxide, indium zinc oxide (IZO), indium tin oxide (ITO) and indium tungsten oxide (IWO), metal nitrides such as titanium nitride, metals such as gold, platinum, silver, chromium, nickel and aluminum, mixtures or stacks of these metals with conductive metal oxides, inorganic conductive substances such as copper iodide and copper sulfide, organic conductive substances such as polyaniline, polythiophene and polypyrrole, stacks thereof with ITO, and so on. Also, use may be made of materials reported in detail in Tomei Dodenmaku no Shintenkai, supervised by Yutaka Sawada (CMC, 1999); Tomei Dodenmaku no Shintenkai II, supervised by Yutaka Sawada (CMC, 2002); Tomei Dodenmaku no Gijutsu, Japan Society for the Promotion of Science (Ohm, 1999) and so on.

As the transparent electrode film material, it is particularly preferable to use any of ITO, IZO, SnO₂, ATO (antimony-doped tin oxide), ZnO, AZO (Al-doped zinc oxide), GZO (gallium-doped zinc oxide), TiO₂ and FTO (fluorine-doped tin oxide). The light transmittance of a transparent electrode film at the photoelectric conversion light absorption peak wavelength of the photoelectric conversion layer contained in the photoelectric conversion device having the transparent electrode film is preferably 60% or more, still preferably 80% or more, still preferably 90% or more and still preferably 95% or more. The preferable range of the surface resistance of the transparent electrode film varies depending on, for example, whether being a pixel electrode or a counter electrode and whether the charge storage/transfer/reading part having a CCD structure or a CMOS structure. In the case of using the transparent electrode film as a counter electrode and the charge storage/transfer/reading part having a CMOS structure, the surface resistance is preferably not more than 10000 Ω/□, still preferably not more than 1000 Ω/□. In the case of using the transparent electrode film as a counter electrode and the charge storage/transfer/reading part having a CCD structure, the surface resistance is preferably not more than 1000 Ω/□, still preferably not more than 100 Ω/□. In the case of using as a pixel electrode, the surface resistance is preferably not more than 1000000 Ω/□, still preferably not more than 100000 Ω/□.

Now, film-forming conditions for the transparent electrode film will be described. In the film-forming step of the transparent electrode film, the substrate temperature is preferably 500° C. or below, still preferably 300° C. or below, still preferably 200° C. or below and still preferably 150° C. or below. A gas may be introduced during the transparent electrode film formation. Although the gas is not fundamentally restricted in species, use may be made of Ar, He, oxygen, nitrogen or the like. It is also possible to use a mixture of these gases. In the case of using an oxide material, it is preferable to use oxygen since there frequently arises oxygen defect.

It is preferable to apply a voltage to the photoelectric conversion layer of the invention to improve the photoelectric conversion efficiency. Although the application voltage may be an arbitrary one, the required voltage level varies depending on the thickness of the photoelectric conversion layer. That is to say, a higher photoelectric conversion efficiency is obtained under the larger electric field applied to the photoelectric conversion layer. In the case of applying a definite voltage, the electric field is increased with a decrease in the thickness of the photoelectric conversion layer. In the case of using a thin photoelectric conversion layer, therefore, the applied voltage may be relatively low. The electric field to be applied to the photoelectric conversion layer is preferably 10 V/m or more, still preferably 1×10³ V/m or more, still preferably 1×10⁵ V/m or more, particularly preferably 1×10⁶ V/m or more and most desirably 1×10⁷ V/m or more. Although the upper limit thereof is not particularly specified, it is undesirable to apply an excessive electric field since a current flows even in a dark place in such a case. Thus, the electric field to be applied is preferably 1×10¹² V/m or less, still preferably 1×10⁹ V/m or less.

(Inorganic Layer)

Now, an inorganic layer serving as the electromagnetic wave absorption/photoelectric conversion part will be illustrated. In this case, light passing through the upper organic layer is photoelectrically converted in the inorganic layer. As the inorganic layer, use is generally made of a pn junction or a pin junction of semiconductor compounds such as crystalline silicone, amorphous silicone and GaAs. As a stacked structure, a method disclosed by U.S. Pat. No. 5,965,875 may be employed. Namely, this method comprises forming a photo acceptance part stacked with the use of the wavelength-dependency of the absorption coefficient of silicone and performing color separation in the depth direction thereof. Since the color separation is carried out depending on the light transmission depth of silicone in this case, the spectra detected in individual acceptance parts stacked together have each a broad range. By using the organic layer as the upper layer as described above (i.e., detecting light transmitting the organic layer in the depth direction of silicone), however, the color separation can be remarkably improved. By providing a G layer as the organic layer, in particular, light transmitting through the organic layer is separated into B light and R light. As a result, the light may be divided merely into BR lights in the depth direction of silicone and thus the color separation is improved. In the case where the organic layer is a B layer or an R layer, the color separation can be remarkably improved too by appropriately selecting the electromagnetic wave absorption/photoelectric conversion part of silicone along the depth direction. In the case of forming two organic layers, the function as the electromagnetic wave absorption/photoelectric conversion part in silicone may be performed fundamentally in only one color and, in its turn, favorable color separation can be established.

In a preferable case, the inorganic layer has a structure wherein multiple photodiodes are stacked in the depth direction of a semiconductor substrate for individual pixels and color signals corresponding to the signal charges generating in the individual photodiodes due to light absorbed by the multiple photodiodes are read out. It is preferable that the multiple photodiodes involve at least one of a first photodiode located in the depth of absorbing B light and a second photodiode located in the depth of absorbing R light, and each of the photodiodes has a color signal reading circuit for reading a color signal corresponding to each of the signal charges. According to this constitution, color separation can be performed without resorting to a color filter. It is also possible in some cases to detect light in the negative component, which enables color image pickup with favorable color reproducibility. It is preferable in the invention that the joint part of the first photodiode is formed in a depth up to about 0.2 μm from the semiconductor substrate surface, while the joint of the second photodiode is formed in a depth up to about 2 μm from the semiconductor substrate surface.

Now, the inorganic layer will be illustrated in greater detail. Preferable examples of the inorganic layer constitution include photo acceptance devices of the photoconductive type, the p-n junction type, the shot-key junction type, the PIN junction type and the MSM (metal-semiconductor-metal) junction type and photo acceptance devices of the photo transistor type. It is preferable in the invention to employ a photo acceptance device wherein first conductive areas and second conductive areas being opposite to the first conductive areas are alternatively stacked on a single semiconductor substrate and the joint parts of the first conductive areas and the second conductive areas are formed respectively at depths appropriate mainly for the photoelectric conversion of a plural number of lights in different wavelength regions. As the single semiconductor substrate, monocrystalline silicone may be preferably employed. Thus, color separation can be performed by taking advantage of the absorption wavelength characteristics depending on the depth direction of the silicone substrate.

As the inorganic semiconductor, use can be made of InGaN-based, InAlN-based, In AlP-based or InGaAlP-based inorganic semiconductors. An InGaN-based inorganic semiconductor is prepared by appropriately altering the composition of In so as to achieve an absorption peak in the blue light wavelength region. That is to say, it is represented by In_{X}Ga_{l-X}N (0≦X<1) A semiconductor made of such a compound can be produced by the metalorganic chemical vapor deposition method (MOCVD method). An InAlN-based nitride semiconductor with the use of Al belonging to the same group (13) as Ga is also usable as a short wavelength light acceptor part as in the InGaN-based one. Furthermore, use can be also made of InAlP and InGaAlP lattice-matching a GaAs substrate.

The inorganic semiconductor may have an embedded structure. The term “embedded structure” means a constitution wherein both ends of a short wavelength light acceptor part are covered with a semiconductor which is different from the short wavelength light acceptor part. As the semiconductor covering both ends, it is preferable to employ a semiconductor having a band gap wavelength which is shorter than the band gap wavelength of the short wavelength light acceptor part or equals thereto.

The organic layer and the inorganic layer may be bonded in an arbitrary manner. It is preferable to provide an insulating layer between the organic layer and the inorganic layer to thereby electrically insulating them.

An npn-junction or a pnpn-junction, from the incident light side, is preferred. The pnpn-junction is still preferred, since the surface potential can be maintained at a high level by forming a p layer on the surface and thus holes and a dark current generating on the surface can be trapped, thereby lowering the dark current.

In such a photodiode, an n-type layer, a p-type layer, an n-type layer and a p-type layer are deeply formed in this order, i.e., being successively diffused from the p-type silicone substrate surface, and thus a pn-junction diode is formed in the depth direction of the silicone to give four layers (pnpn). Incident light with a longer wavelength entering from the diode surface side the more deeply transmits and the incident wavelength and the attenuation coefficient are inherent to silicone. Thus, the diode is designed so that the pn junction face covers the wavelength region of visible light. Similarly, an n-type layer, a p-type layer and an n-type layer are formed in this order to give a junction diode having three layers (npn). A light signal is taken out from the n-type layer, while the p-type layer is ground connected.

By forming a drawing electrode in each area and applying a definite reset potential thereto, each area becomes depletion and the capacity in each junction part is highly lessened. Thus, the capacity generating in the junction face can be highly lessened.

(Auxiliary Layer)

It is preferable to provide an ultraviolet absorption layer and/or an infrared absorption layer as the uppermost layer of the electromagnetic wave absorption/photoelectric conversion part. The ultraviolet absorption layer can absorb or reflect light having wavelength of at least 400 nm or less and it preferably has an absorption factor in a wavelength region of 400 nm or less of 50% or more. The infrared absorption layer can absorb or reflect light having wavelength of at least 700 nm or more and it preferably has an absorption factor in a wavelength region of 700 nm or more of 50% or more.

These ultraviolet absorption layer and infrared absorption layer can be formed by publicly known methods. For example, there has been known a method which comprises forming a mordant layer made of a hydrophilic polymer such as gelatin, casein, glue or polyvinyl alcohol on the substrate and adding a dye having a desired absorption wavelength to the mordant layer or dyeing the mordant layer to form a color layer. Another known method comprises using a colored resin wherein a specific coloring matter is dispersed in a transparent resin. Moreover, use may be made of a colored resin layer comprising a polyamino resin and a coloring matter, as reported by JP-A-58-46325, JP-A-60-78401, JP-A-60-184202, JP-A-60-184203, JP-A-60-184204, JP-A-60-184205 and so on. It is also possible to use a coloring agent comprising a photosensitive polyimide resin.

Furthermore, it is possible to disperse a coloring matter in an aromatic polyamide resin which has a photosensitive group in its molecule and can provide a hardened layer at 200° C. or below, as reported by JP-B-7-113685. Also, use can be made of a dispersion colored resin in an amount as specified in JP-B-7-69486.

It is preferable to use a dielectric multiple layers. It is preferable to use a dielectric multiple layers, since it has a sharp wavelength-dependency of light transmission.

It is preferable that individual electromagnetic wave absorption/photoelectric conversion parts are separated by insulating layers. These insulating layers can be formed by using transparent insulating materials such as glass, polyethylene, polyethylene terephthalate, polyether sulfone or polypropylene. Also, use may be preferably made of silicon nitride, silicon oxide and the like. A silicon nitride layer formed by the plasma CVD method is preferably used because of being highly dense and highly transparent.

To prevent from direct contact with oxygen or moisture, it is also possible to form a protective layer or a blocking layer. Examples of the protective layer include a diamond layer, layers made of inorganic materials such as metal oxides and metal nitrides, layers made of polymers such as fluororesins, poly(para-xylene), polyethylene, silicone resins and polystyrene resins, and photosetting resins. It is also possible to package the device per se by covering it with glass, a gas non-permeable plastic, a metal, etc. In this case, it is also possible to enclose a substance having a high water absorption in the package.

Furthermore, an embodiment wherein a microlens array is formed in the upper part of the light-receiving device so as to improve the light collection efficiency.

(Charge Storage/Transfer/Reading Part)

Concerning the charge storage/transfer/reading part, reference may be made to JP-A-58-103166, JP-A-58-103165, JP-A-2003-332551 and so on. Namely, use may be appropriately made of a constitution wherein MOS transistors are formed for individual pixels on a semiconductor substrate or a constitution having CCD as a device. In the case of a photoelectric conversion device with the use of MOS transistors, for example, electric charge arises in a photoconductive layer due to incident light transmitting through electrodes. By applying a voltage to the electrodes, an electric field is formed between the electrodes and thus the charge migrates across the photoconductive layer toward the electrodes. Then the charge enters into a charge storage part in the MOS transistor and stored therein. The charge stored in the charge storage part transfers to a charge-reading part by switching the MOS transistor and then output as an electric signal. Owing to this mechanism, a full color image signals are input in the solid-state image pickup device having a signal processing part.

It is also possible that a definite amount of bias charge is injected into a storage diode (a refresh mode) and, after storing a definite charge (a photoelectric conversion mode), the signal charge is read out. It is possible to use a photo acceptance device per se as a storage diode or to separately provide a storage diode.

Next, signal reading will be illustrated in greater detail. Signals can be read by using a conventional color reading circuit. A signal charge or a signal current phtoelectrically converted in the photo acceptance part is stored in the photo acceptance part per se or a capacitor provided separately. The thus stored charge is read simultaneously with the selection of pixel position by the means of MOS image pickup device with the use of the X-Y address system (a so-called CMOS sensor). As another reading method, an address selection system which comprises successively selecting pixels one by one with a multi prexar switch and a digital shift switch and reading as a signal voltage (or charge) along a common output curve may be cited. There is an image pickup device with the use of a two-dimensionally arrayed X-Y address operation which is known as a CMSO sensor. In this device, a switch attached to the X-Y intersection is connected to a perpendicular shift resistor. When the switch is turned on by the voltage from the perpendicular scanning shift resistor, signals read from pixels in the same line are read along the output curve in the ray direction. These signals are read one by one from the output end through a switching mechanism which is driven by a horizontal scanning shift resistor.

To read output signals, use can be made of a floating diffusion detector or a floating gate detector. Moreover, S/N can be improved by providing pixels with a signal amplification circuit or using the correlated double sampling method.

Signals can be processed by using gamma correlation with the use of an ADC circuit, digitalization with the use of an AD converter, the luminance signal processing method or the color signal processing method. Examples of the color signal processing method include white balance processing, color separation processing, color matrix processing and so on. In order to use as NTSC signals, the RGB signals can be converted into YIQ signals.

In the charge transfer/reading part, the charge migration rate should be 100 cm²/volt sec or higher. Such a migration rate can be established by selecting an appropriate semiconductor material belonging to the group IV, III-V or II-VI. Among all, it is preferable to employ silicone semiconductors, since fine processing techniques have advanced in this field and they are available at low cost. There have been proposed a large number of charge transfer/charge reading systems and any of these systems is usable. A CMSO-type or CCD-type device system is particularly preferred. In the invention, the CMSO-type system is preferred in various points including high-speed reading, pixel integration, partial reading and power consumption.

(Connection)

Multiple parts for connecting the electromagnetic wave absorption/photoelectric conversion part to the charge storage/transfer/reading part may be made of any metal. It is preferable to use a metal selected from among copper, aluminum, silver, gold, chromium and tungsten and copper is particularly preferable therefor. Contact parts should be respectively provided between individual electromagnetic wave absorption/photoelectric conversion parts and individual charge storage/transfer/reading parts. In the case of using a stacked structure comprising blue, green and red light photosensitive units, it is necessary to connect a fetch electrode for blue light to a charge transfer/reading part, to connect a fetch electrode for green light to a charge transfer/reading part and to connect a fetch electrode for red light to a charge transfer/reading part respectively.

(Process)

The stacked photoelectric conversion device according to the invention can be fabricated in accordance with a so-called micro fabrication process employed in fabricating publicly known integrated circuits and so on. In this process, the following procedures are repeated fundamentally: pattern exposure with the use of active rays or electron beams (i, g bright-line of mercury, eximer laser, X-ray, electron beams, etc.); pattern formation by development and/or burning; provision of device-forming materials (coating, vapor deposition, sputtering, CV, etc.); and removal of the materials from non-pattern areas (heating, dissolution, etc.).

(Use)

Concerning the chip size, the device may have the brownie size, the 135 size, the APS size, the 1/1.8 size or a smaller size. In the stacked photoelectric conversion device of the invention, the pixel size is expressed in diameter of a circle corresponding to the maximum area of multiple electromagnetic wave absorption/photoelectric conversion parts. Although any pixel size may be used, a pixel size of 2 to 20 μm is preferable, still preferably 2 to 10 μm and particularly preferably 3 to 8 μm.

In the case where the pixel size exceeds 20 μm, the resolution is lowered. In the case where the pixel size is less than 2 μm, the resolution is also lowered due to radio interference among sizes.

The photoelectric conversion device of the invention is usable in digital still cameras. It is also preferably usable in TV cameras. In addition thereto, the photoelectric conversion device of the invention is usable in digital video cameras, monitor cameras (to be used in, for example, office buildings, parking areas, financial institutions, automatic loan-application machines, shopping centers, convenience stores, outlet malls, department stores, pinball parlors, karaoke boxes, game centers and hospitals), image pickup devices such as facsimiles, scanners and copying machines, other various sensors (entrance monitors, identification sensors, sensors for factory automation, robots for household use, robots for industrial use and pipe inspection systems), medical sensors (endoscopes and fundus cameras), TV conference systems, TV telephones, camera-equipped cell phones, safe driving systems for automobiles (back guide monitors, collision-estimating systems and lane-keeping systems), sensors for TV games and so on.

Among all, the photoelectric conversion device of the invention is appropriately usable in TV cameras. This is because the photoelectric conversion device of the invention requires no optical system for color separation and thus contributes to the reduction in size and weight of TV cameras. Moreover, it has a high sensitivity and a high resolution and, therefore, is particularly preferable in TV cameras for high-definition broadcast, The TV cameras for high-definition broadcast as used herein include cameras for digital high-definition broadcast.

The photoelectric conversion device of the invention requires no optical low pass filter, which makes it further preferable from the viewpoint of achieving an increased sensitivity and improved resolution.

Furthermore, the thickness of the photoelectric conversion device according to the invention can be lessened and no optical system for color separation is required therein. Thus, it can provide a single camera which meets various photography-related needs. Namely, scenes wherein different sensitivities are needed, e.g., “environments with a change in brightness, e.g., daytime and night”, “a still subject and a moving subject” and so on, and scenes wherein different spectral sensitivities or color reproductions are needed can be taken with the use of a single camera merely replacing the photoelectric conversion devices of the invention. Therefore, it becomes unnecessary to carry a plural number of cameras, which lessen the load on a photographer. To replace the photoelectric conversion devices, the above-described photoelectric conversion device is prepared together with spare photoelectric conversion devices for, e.g., infrared light photographing, monochromic photographing, dynamic range replacement and so on.

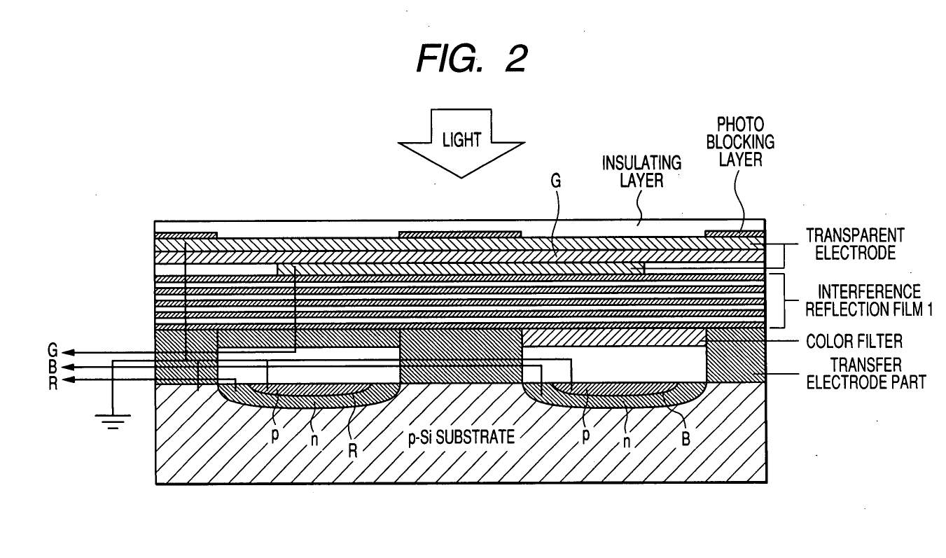

The TV camera according to the invention can be fabricated by reference to Terebijon Kamera no Sekkei Gijutsu, ed. by The Institute of Image Information and Television Engineers (1999, Corona) chap. 2 and replacing, for example, the optical system for color separation and the image pickup device in FIG. 2.1 (Fundamental Constitution of TV Camera) therein by the photoelectric conversion device of the invention.

The stacked photo acceptance devices as described above may be used as an image pickup device by aligning. Alternatively, a single device can be used as a photo sensor or a color photo acceptance device in biosensors and chemical sensors.

(Optical Film)

In the stack type photoelectric conversion device of the invention, a single layer or multilayer optical film is formed so as to increase the reflectivity of light within the wavelength range capable of being absorbed by the photoelectric conversion layer located in the light-incident side concerning the optical film (for example, the photoelectric conversion layer located above the substrate or an organic photoelectric conversion layer located in the light-incident side concerning the optical film), compared with the case wherein no optical film is formed. In usual, the optical film is provided so that it transmits as far as possible the light within the wavelength range absorbed by the photoelectric conversion layer located opposite to the light-incident side concerning the optical film (for example, the photoelectric conversion part located in the substrate a or an organic photoelectric conversion layer located opposite to the light-incident side concerning the optical film). In this case, it is also possible to increase the transmittance of light in the wavelength range absorbed by the photoelectric conversion layer located opposite to the light-incident side concerning the optical film compared with the case of forming no optical film.

Owing to the absorption of the light reflected from the optical film, the sensitivity of the photoelectric conversion layer in the light-incident side can be improved. By appropriately adjusting the optical thickness of the photoelectric conversion layer, it also becomes possible to sharpen the spectral sensitivity of light absorption due to the interference effect in the photoelectric conversion layer. Since the optical film reflects unnecessary light but transmits necessary light, the light color separation of the photoelectric conversion layer located opposite to the light-incident side can be also improved.

As such an optical film capable of reflecting light having a desired wavelength range and transmitting lights of other wavelength ranges, use can be made of, for example, an optical interference film comprising two layers, which have different refraction indexes, alternately stacked.

As these two layers having different refraction indexes, it is preferable to employ multiple layers made of two materials, the refraction index ratio (i.e., the value determined by dividing the higher refraction index by the lower refraction index) of which is 1.1 or higher but not higher than 1.3, alternately stacked and at least one of these two materials being an insulator.

Examples of the materials constituting the optical film include silicon oxide, silicon nitride, silicon oxynitride, titanium oxide, alumina, zirconium oxide, hafnium oxide, magnesium fluoride, calcium fluoride and so on.

Examples of the method of forming the optical film include film-formation methods such as the vacuum vapor deposition method, the sputtering method, the plasma CVD method, the cat-CVD method, the laser ablation method and so on.

The optical film is formed usually between multiple photoelectric conversion layers responding to lights of different wavelength ranges, for example, between the photoelectric conversion part located in the substrate and the photoelectric conversion layer located above the substrate. In the case where all of photoelectric conversion layers are organic photoelectric conversion layers, the optical film may be located opposite to the light-incident side concerning the all photoelectric conversion layers. In this case, it is not required that the optical film transmits light.

Next, the invention will be described in greater detail by referring to Examples.

### EXAMPLES

### Example 1

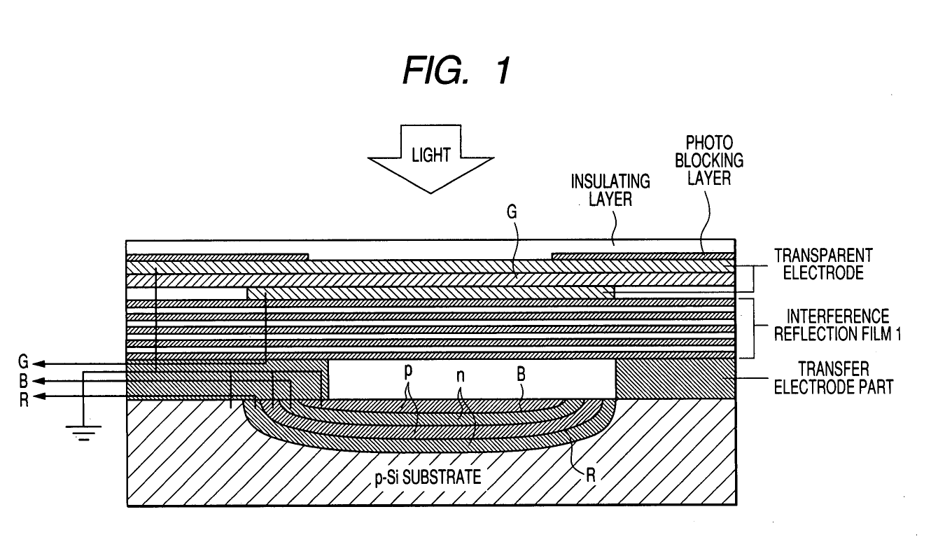

FIG. 1 is a schematic drawing which shows a device of according to Example 1 of the invention.

The device of FIG. 1 is a stack type image pickup device comprising a photoelectric conversion layer G for green color detection, a photoelectric conversion layer B for blue color detection and a photoelectric conversion layer R for red color detection which are stacked in this order. For the green color detection, use is made of a photoelectric conversion layer G which comprises an organic semiconductor having an absorption spectrum peak in the green region. Blue and red colors are separated by taking advantage of a difference in the absorption length at individual light-receiving parts in a photoelectric conversion part stacked within an Si substrate. In the constitution of FIG. 1, an organic photoelectric conversion layer G corresponds to “photoelectric conversion layer located above the substrate” while the photoelectric conversion parts B and R with the pnpn structure formed within the lower Si substrate correspond to “photoelectric conversion part located in the substrate”. Under the organic photoelectric conversion layer G, there is provided an interference reflection layer 1 designed as increasing the reflectivity of green light as “optical film”. Thus, the sensitivity of the organic photoelectric conversion layer G is improved and the transmittance of green light to the lower parts is suppressed while allowing the transmittance of blue and red lights. After passing through the organic photoelectric conversion layer G and the interference reflection layer 1, the blue or red light is detected in the blue or red photoelectric conversion layer B or R in the photoelectric conversion part located in the substrate.

The device shown in FIG. 1, green light is received by the organic photoelectric conversion layer G serving as the upper layer while red and blue lights are received by the lower photoelectric conversion part located in the Si substrate. However, the invention is not restricted thereto. For example, it is also possible to employ a constitution wherein blue light is received by the organic photoelectric conversion layer serving as the upper layer while green and red lights are received by the lower photoelectric conversion part located in the Si substrate. In this case, an interference reflection layer designed so as to increase the reflectivity of blue light is provided under the organic photoelectric conversion layer. However, the organic photoelectric conversion layer serving as the upper layer has the highest light utilization efficiency and, therefore, it is preferable from the viewpoint of visibility to form the organic photoelectric conversion layer G receiving green light as the organic photoelectric conversion layer of the upper layer.

Even though the absorption is broad, the spectral sensitivity of the blue or red photoelectric conversion part can be sharpened by cutting short wavelength or long wavelength light respectively by an ultraviolet cut filter or an infrared cut filter. However, this method cannot be used for green light. In the case where the absorption by a photoelectric conversion layer is broad, therefore, it is highly effective to provide an interference reflection layer under the green light photoelectric conversion layer to thereby sharpen the green light absorption by the interference effect between the incident light and the reflected light. From this viewpoint, it is also preferred to employ the organic photoelectric conversion layer G receiving green light as the organic photoelectric conversion layer of the upper layer.

Owing to this constitution, the difficulties in the production process for connecting to a transfer circuit can be largely lessened compared with the case of stacked multiple photoelectric conversion layers on the substrate. By employing an organic material having a large absorption coefficient of green light, the thickness of the photoelectric conversion layer can be regulated and thus the difficulties can be moreover lessened.

Under the photoelectric conversion layer G for green color detection, multiple layers of silicon oxynitride and silicon oxide are stacked, thereby forming an optical interference layer 1. By this optical interference layer 1, the reflectivity of green light is increased and the sensitivity of the photoelectric conversion layer G for green color detection is improved while the transmittance of green light toward the lower silicone photoelectric conversion parts B and R is regulated. Since the refraction index of an organic layer widely varies depending on incident light wavelength, the interference effect achieved by the optical interference layer 1 widely varies depending on the wavelength. By using this phenomenon, the light absorption wavelength range can be sharpened.

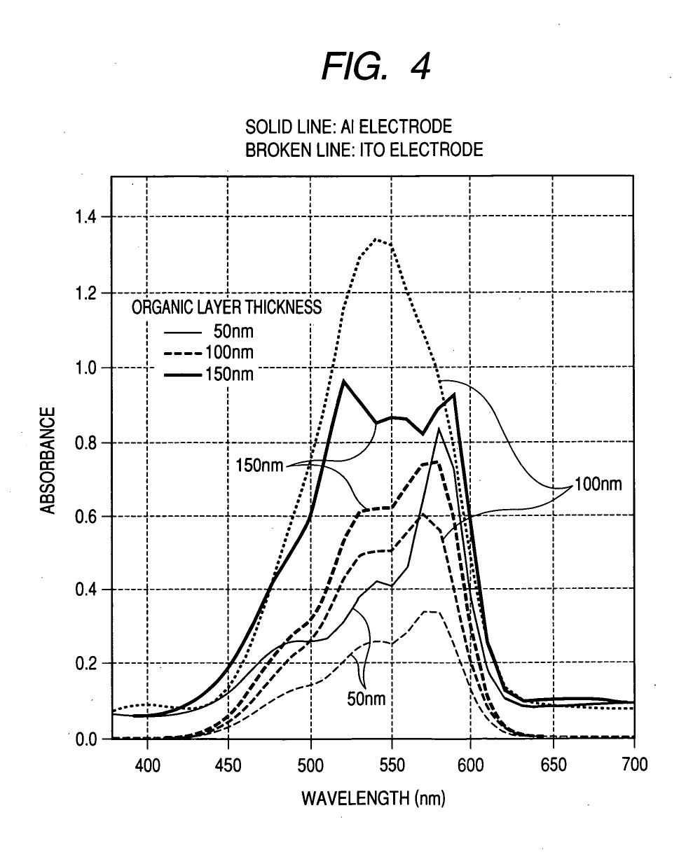

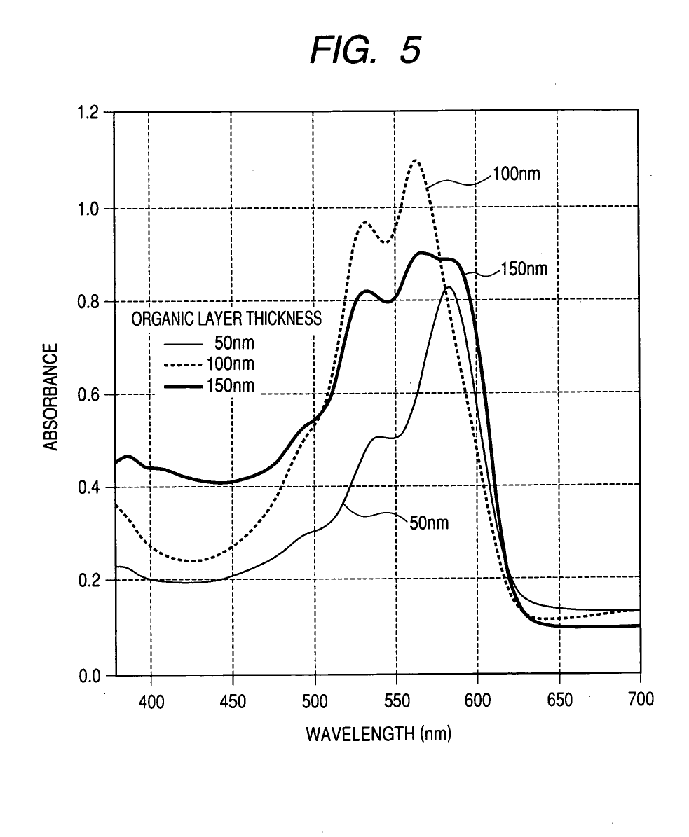

The broken lines in FIG. 4 show the calculated absorption spectral data of photoelectric conversion layers in which a quinacridone-based organic film is sandwiched between ITO films. As the optical constants of the organic film, use is made of values experimentally determined by ellipsometry. By providing an Al reflection film opposite to the light-incident side of this layer, the absorbance can be improved as shown by the solid lines in FIG. 4. The absorbance at a thickness of 100 nm shows a particularly large increase owing to the interference effect. It can be also understood that the absorption spectrum of this layer is sharpened by the interference effect. FIG. 5 shows the measured absorption spectral data of the same photoelectric conversion layers. It can be understood that the calculated data of FIG. 4 are roughly reproduced. A photoelectric conversion layer was fabricated by forming individual deposition films as follows. In a vacuum chamber at 4×10⁻⁴ Pa, a quinacridone-based organic material was vacuum deposited at a deposition rate of about 1 A/s to give a thickness of 100 nm on a glass substrate having an ITO film of 250 nm in thickness formed thereon. Further, Al was vacuum deposited thereon at a deposition rate of about 3 A/s to give a thickness of 100 nm. An absorption spectrum was measured by using a spectrophotometer provided with an integrating sphere capable of collecting reflected and scattered rays.

These results indicate that the formation of a reflection film opposite to the light-incident side concerning a photoelectric conversion layer is effective in increasing the absorption factor and sharpening the absorption band.

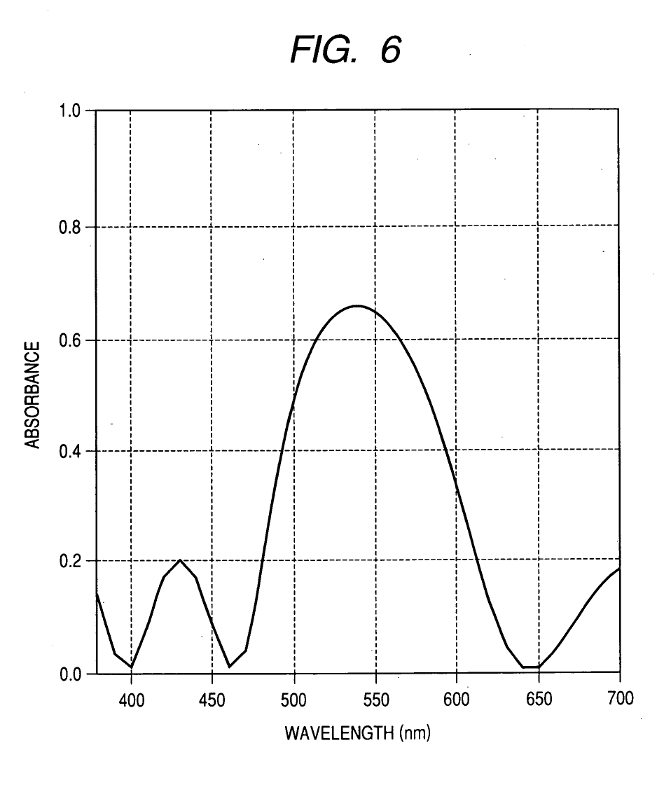

In Example 1, however, it is required that an optical film to be used in a photoelectric conversion device in practice should transmit blue light and red light. As an example of such an organic photoelectric conversion layer, an optical interference film having alternately stacked multiple layers of silicon oxynitride and silicon oxide may be cited. FIG. 6 shows the reflectivity of atmospheric incident light by a film consisting of five silicon oxynitride layers (79 nm, refractive index 1.71) and four silicon oxide layers (92 nm, refractive index 1.460) alternately stacked, i.e., nine layers in total. It can be understood that green light alone can be efficiently reflected by using this optical interference film.

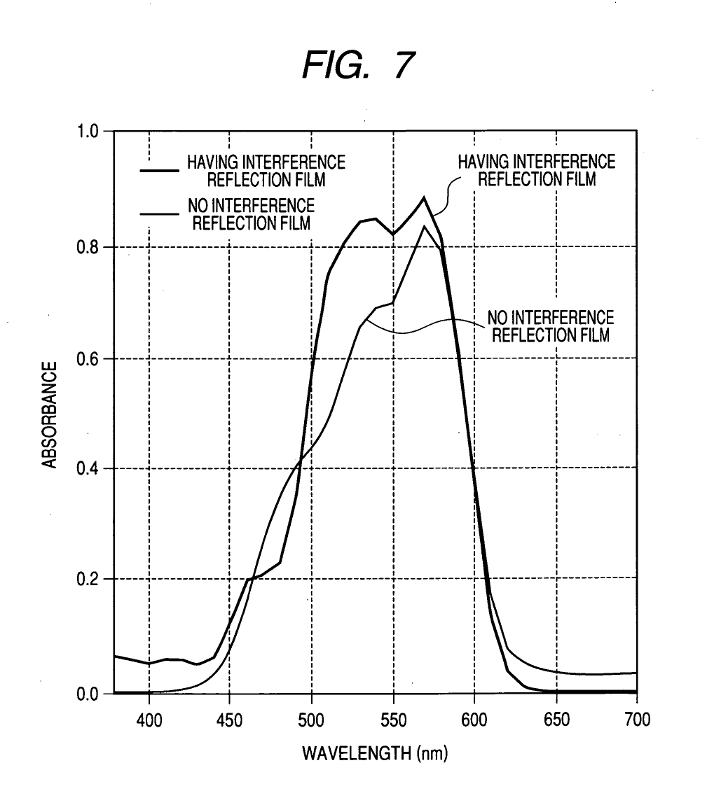

By combining such an optical interference film as described above with an organic film sandwiched between transparent electrodes, the light absorption factor of the organic film can be increased. FIG. 7 shows a simulation result. In this simulation, calculation was made on a structure consisting of 14 layers, i.e., from the light-incident (atmosphere) side, a silicone nitride layer (100 nm, refractive index 1.9), a transparent electrode (100 nm, refractive index 1.9), an organic film (100 nm) and a transparent electrode (100 nm, refractive index 1.9), and five pairs of a silicon oxide layer (92 nm, refractive index 1.46) with a silicon oxynitride layer (79 nm, refractive index 1.71). The organic film is made of a quinacridone-based compound. As optical constants, use is mad of values experimentally determined by ellipsometry. As FIG. 7 indicates, the green light absorption factor of the organic film can be increased by forming the optical interference film (a largest increase of 0.26 at 510 nm). Furthermore, a more appropriate spectral sensitivity as a photoelectric conversion layer to green light can be obtained.

The material of the insulating layer is not restricted to those cited above but use may be made of an arbitrary material so long as it is highly transparent and excellent in fastness, denseness, smoothness and adhesiveness. Examples of materials usable therefor include transparent insulating materials, e.g., inorganic materials such as silicon nitride, silicon oxide, silicon oxynitride, titanium oxide, alumina, zirconium oxide, hafnium oxide, magnesium fluoride, calcium fluoride and so on and organic materials such as polyvinyl chloride, polyethylene, polyethylene terephthalate, polystyrene, polyether sulfone, polypropylene and so on. From the viewpoints of heat stability and insulating resistance, inorganic materials are preferred. From the viewpoints of cost and refractive index ratio controlling properties, silicon nitride, silicon oxide and silicon oxynitride are still preferred.

Examples of a method of forming an optical film with the use of an inorganic material include the vacuum vapor deposition method, the sputtering method, the plasma CVD method, the Cat-CVD method, the laser ablation method, the MBE method and so on. Among these methods, the vacuum vapor deposition method includes the resistance heating method, the electron beam heating/deposition method and so on. To combine these methods so as to improve the uniformity and smoothness of the film and control the stoichiometric ratio thereof, use can be also made of the ion beam assist method, the ion plating method, the reactive deposition method and so on. The sputtering method include the dipolar sputtering method, the magnetron sputtering method, the ECR sputtering method, the high-frequency sputtering method and so on. To improve the film uniformity or overcome the problems of contamination, use may be made of the reactive sputtering method or the ion beam sputtering method. The plasma CVD method includes those with the use of a plasma source such as dipolar discharge, magnetron discharge, ECR discharge or dielectric plasma discharge. In the method of using dielectric plasma discharge, furthermore, use can be made mainly made of ICP discharge, Helicon wave discharge, TCP discharge or SWP discharge. Among these production methods, the electron beam deposition method is favorable from the viewpoint of forming a film of a high-melting material at a low cost, while the sputtering method is favorable from the viewpoint of film denseness.

### Example 2

FIG. 2 shows a photoelectric conversion device in which an interference reflection layer 1 is formed under an organic green light photoelectric conversion layer G similar to FIG. 1, while blue light- and red light-receiving parts B and R are provided not in the depth direction but in the horizontal direction separately in a lower photoelectric conversion part in an Si substrate. In this case, blue and red lights are separated in Si and thus each light-receiving part is provided with a color filter.

In the constitution of FIG. 2, green light is received by the organic photoelectric conversion layer G of the upper layer and red and blue lights are received by the lower photoelectric conversion part in the Si substrate. However, the invention is not restricted thereto. It is also possible to employ a constitution wherein, for example, blue light is received by the organic photoelectric conversion layer of the upper layer and green and red lights are received by the lower photoelectric conversion part in the Si substrate. In this case, an interference reflection layer having such a thickness as increasing the reflectivity of blue light is formed under the organic photoelectric conversion layer. However, the organic photoelectric conversion layer serving as the upper layer has the highest light utilization efficiency and, therefore, it is preferable from the viewpoint of visibility to form the organic photoelectric conversion layer G receiving green light as the organic photoelectric conversion layer of the upper layer.

Even though the absorption is broad, the blue or red photoelectric conversion layer can sharpen the spectral sensitivity by cutting short wavelength or long wavelength light respectively by an ultraviolet cut filter or an infrared cut filter. However, this method cannot be used for green light. In the case where the absorption by a photoelectric conversion layer is broad, therefore, it is highly effective to provide an interference reflection layer under the green light photoelectric conversion layer to thereby sharpen the green light absorption by the interference effect between the incident light and the reflected light. From this viewpoint, it is also preferred to employ the organic photoelectric conversion layer G receiving green light as the organic photoelectric conversion layer of the upper layer.

Owing to this constitution, the difficulties in the production process for connecting to a transfer circuit can be largely lessened compared with the case of stacked multiple photoelectric conversion layer layers on the substrate. By employing an organic material having a large absorption coefficient of green light, the thickness of the photoelectric conversion layer can be regulated and thus the difficulties can be moreover lessened.

### Example 3

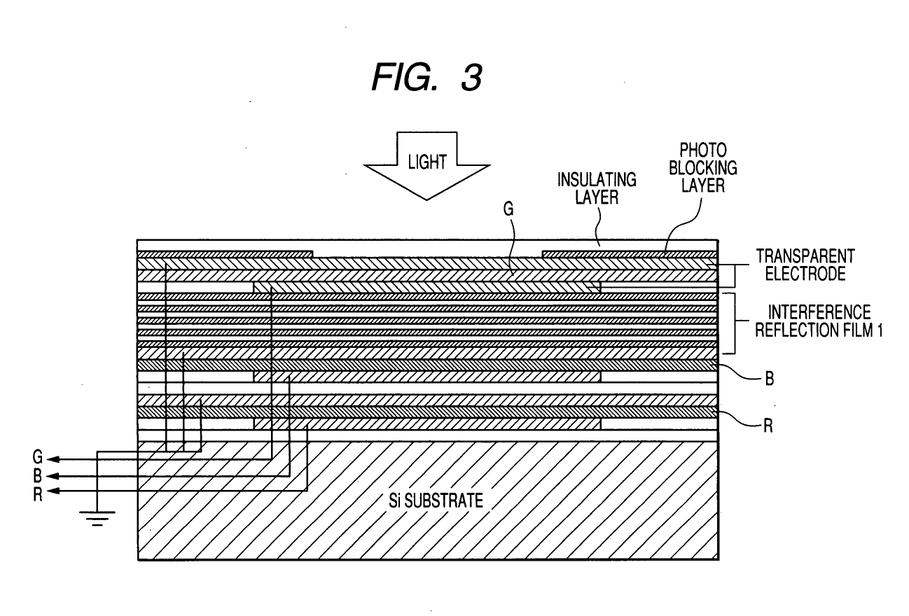

FIG. 3 shows a photoelectric conversion device in which all of the green, blue and red light-receiving layers comprise organic photoelectric conversion layers G, B and R. To detect green, blue and red lights, photoelectric conversion layers G, B and R which are made of organic semiconductors having respectively at green, blue and red absorption spectral peaks. Under the organic photoelectric conversion layer G serving as the uppermost layer, an interference reflection layer 1, which is designed so as to increase the reflectivity of green light, is formed and thus the sensitivity of the photoelectric conversion layer G for green color detection is increased and the transmittance of green light toward the lower organic photoelectric conversion layers B and R is suppressed.

Although the green layer, the blue layer and the red layer are stacked in this order from the top side in FIG. 3, the invention is not restricted thereto. Also, it is not always necessary that the interference reflection layer is formed between the photoelectric conversion layer located at the closest position to the light-incident side and the organic photoelectric conversion layer located at the second closest position. For example, use may be made of a constitution wherein photoelectric conversion layers are stacked in the order of blue, red and green from the top side and an optical film capable of increasing the reflectivities of blue and red lights is formed between the red and green photoelectric conversion layers By considering the light loss, etc. in an insulator or an organic layer, however, the organic photoelectric conversion layer serving as the upper layer has the highest light utilization efficiency and, therefore, it is preferable from the viewpoint of visibility to provide a green light-receiving layer as the photoelectric conversion layer at the closest position to the light-incident side and form an optical film capable of increasing the reflectivity of green light between this photoelectric conversion layer and the next photoelectric conversion layer.

In this constitution, the thickness of the photoelectric conversion layer can be regulated and thus the difficulties can be moreover lessened by employing an organic material having a large absorption coefficient of green light.

Also, use may be made of a constitution wherein multiple pairs of optical films are formed. In Example 3, it is also possible to form an optical film capable of increasing the reflectivities of green light and blue light between the blue light-receiving photoelectric conversion layer and the red light-receiving photoelectric conversion layer.

### Example 4

In the photoelectric conversion device of this Example, all of the green, blue and red light-receiving layers comprise organic photoelectric conversion layers G, B and R as in Example 3 but reflection layers 1 made of aluminum are provided as optical films under all of the organic photoelectric conversion layers G, B and R, thereby increasing the sensitivities of all of the organic photoelectric conversion layers G, B and R.

Although the layers are stacked in the order of green, blue and red from the top side in this case, the invention is not restricted thereto. By considering the light loss, etc. in an insulator or an organic layer, however, the organic photoelectric conversion layer serving as the upper layer has the highest light utilization efficiency and, therefore, it is preferable from the viewpoint of visibility to provide a green light-receiving layer as the photoelectric conversion layer at the closest position to the light-incident side.

Also, use may be made of a constitution wherein multiple pairs of optical films are formed. In Example 4, it is also possible to form an optical film capable of increasing the reflectivities of green light between the green light-receiving photoelectric conversion layer and the blue light-receiving photoelectric conversion layer. Moreover, it is possible to form an optical film capable of increasing the reflectivities of green light and blue light between the blue light-receiving photoelectric conversion layer and the red light-receiving photoelectric conversion layer.

This application is based on Japanese Patent application JP 2005-54503, filed Feb. 28, 2005, and Japanese Patent application JP 2005-186935, filed Jun. 27, 2005, the entire contents of which are hereby incorporated by reference, the same as if set forth at length.

What is claimed is:

1. A photoelectric conversion device comprising:
a substrate including a photoelectric conversion part;
at least one photoelectric conversion layer provided above the substrate; and
an optical film for increasing a reflectivity of light within a wavelength range capable of being absorbed by the photoelectric conversion layer,
wherein the optical film is provided between the photoelectric conversion part and the photoelectric conversion layer.

2. The photoelectric conversion device as claimed in claim 1, wherein the photoelectric conversion layer has such a thickness that a spectral sensitivity thereof is sharpened by an interference effect due to a light reflected from the optical film.

3. The photoelectric conversion device as claimed in claim 1, wherein the photoelectric conversion part includes multiple first conductive areas and multiple second conductive areas of opposite conductive type to the first conductive areas, and the photoelectric conversion part is formed so that first conductive type/second conductive type junction faces are provided at appropriate positions mainly for photoelectric conversion of lights in any two of blue, green and red wavelength ranges respectively, while the photoelectric conversion layer is for responding mainly to the remainder wavelength range differing from the two wavelength ranges.

4. The photoelectric conversion device as claimed in claim 3, wherein the photoelectric conversion part includes two parts provided at positions mainly for photoelectric conversion of lights in blue and red wavelength ranges respectively, while the photoelectric conversion layer is an organic photoelectric conversion layer for responding mainly to an intermediate wavelength range between the blue and red wavelength ranges.

5. The photoelectric conversion device as claimed claim 1, wherein the photoelectric conversion part comprises Si substrate.

6. The photoelectric conversion device as claimed in claim 5, wherein the Si substrate is a p substrate or an n substrate having p-well, and the photoelectric conversion part includes an n-type layer, a p-type layer and an n-type layer in this order, or includes a p-type layer, an n-type layer, a p-type layer and an n-type layer in this order.

7. The photoelectric conversion device as claimed in claim 1, wherein the photoelectric conversion part is formed so as to photoelectrically convert mainly lights in two of blue, green and red wavelength ranges at different positions concerning a face direction perpendicular to a light-incident direction, while the photoelectric conversion layer is for responding mainly to the remainder wavelength range differing from the two wavelength ranges.

8. The photoelectric conversion device as claimed in claim 7, wherein the photoelectric conversion part is formed so as to photoelectrically convert mainly lights in the blue and red wavelength ranges respectively, while the photoelectric conversion layer is an organic photoelectric conversion layer responding mainly to an intermediate wavelength range between the blue and red wavelength ranges.

9. The photoelectric conversion device as claimed in claim 7, wherein the photoelectric conversion part is Si substrate.

10. The photoelectric conversion device as claimed in claim 9, wherein the Si substrate is a p substrate or an n substrate having p-well, and the photoelectric conversion part has an n structure or a pn structure from surface.

11. A photoelectric conversion device comprising: at least two organic photoelectric conversion layers for responding to lights in different wavelength ranges; and an optical film provided between the organic photoelectric conversion layers, the optical film being for increasing a reflectivity of light within a wavelength range capable of being absorbed by the organic photoelectric conversion layer located in a light-incident side.

12. The photoelectric conversion device as claimed in claim 11, wherein the organic photoelectric conversion layer located in the light-incident side has such a thickness that a spectral sensitivity thereof is sharpened by an interference effect due to a light reflected from the optical film.

13. The photoelectric conversion device as claimed in claim 11, wherein the at least two organic photoelectric conversion layers respond mainly to any of lights in the blue, green and red wavelength ranges respectively.

14. The photoelectric conversion device as claimed in claim 11, wherein an organic photoelectric conversion layer for responding mainly to light in the green wavelength range is provided at the closest position to the light-incident side and an optical film being capable for increasing a reflectivity of green light is provided between the green light-responsive organic photoelectric conversion layer and the organic photoelectric conversion layer located at the second closest position to the light-incident side.

15. A photoelectric conversion device comprising: at least two organic photoelectric conversion layers for responding to lights in different wavelength ranges and an optical film located in opposite side to a light-incident side concerning all of the organic photoelectric conversion layers and being capable of increasing a reflectivity of light in a wavelength range capable of being absorbed by at least one of the organic photoelectric conversion layers.

16. The photoelectric conversion device as claimed in claim 15, wherein the at least one organic photoelectric conversion layer has such a thickness that a spectral sensitivity thereof is sharpened by an interference effect due to a light reflected from the optical film.

17. The photoelectric conversion device as claimed in claim 15, wherein the at least two organic photoelectric conversion layers respond mainly to any of lights in the blue, green and red wavelength ranges respectively.

18. The photoelectric conversion device as claimed in claim 15, wherein an organic photoelectric conversion layer responding mainly to light in the green wavelength range is provided at the closest position to the light-incident side and an optical film being capable of increasing a reflectivities of all of lights in the blue, green and red wavelength ranges is provided.

19. The photoelectric conversion device as claimed in claim 1, wherein the optical film reflects light having one of wavelengths 460 nm, 540 nm and 620 nm at a ratio of 50% or more, and transmits lights of other two wavelengths selected from 460 nm, 540 nm and 620 nm at a ratio of 70% or more.

20. The photoelectric conversion device as claimed in claim 1, wherein the optical film reflects light having a wavelength of 540 nm at a ratio of 50% or more, and transmits lights of 460 nm and 620 nm at a ratio of 70% or more.

21. The photoelectric conversion device as claimed in claim 1, wherein the optical film includes at least two insulator layers.

22. The photoelectric conversion device as claimed in claim 21, wherein the optical film has a structure comprising multiple layers made of two materials, a refraction index ratio of which is from 1.1 to 1.3, alternately stacked, and at least one of the two materials is an insulator.

23. The photoelectric conversion device as claimed in claim 21, wherein the optical film includes a layer containing a material selected from the group consisting of silicon oxide, silicon nitride, silicon oxynitride, titanium oxide, alumina, zirconium oxide, hafnium oxide, magnesium fluoride and calcium fluoride.

24. The photoelectric conversion device as claimed in claim 1, wherein the optical film is formed by a method selected from the group consisting of a vacuum vapor deposition method, a sputtering method, a plasma CVD method, a Cat-CVD method and a laser ablation method.
